(19) United States
(12) Patent Application Publication
(10) Pub. No.: US 2011/0215357 A1
(43) Pub. Date: Sep. 8, 2011

(54) LED PACKAGE STRUCTURE AND METHOD OF MANUFACTURING THE SAME

(75) Inventors: BILY WANG, Hsinchu City (TW); SUNG-YI HSIAO, Miaoli County (TW)

(73) Assignee: HARVATEK CORPORATION, HSINCHU CITY (TW)

(21) Appl. No.: 13/004,202

(22) Filed: Jan. 11, 2011

(30) Foreign Application Priority Data
Mar. 8, 2010 (TW) 99106591

(51) Int. Cl. H01L 33/58; H01L 33/48

(52) U.S. Cl. 257/98; 438/27; 257/E33.056; 257/E33.067

(57) ABSTRACT

An LED package structure for increasing heat-dissipating efficiency includes providing a substrate element; removing one part of the substrate element in order to form at least two substrate bodies separated from each other and at least one gap between the at least two substrate bodies; forming at least one

[symbol]

### BACKGROUND OF THE INVENTION

1. Field of the Invention

The present invention relates to an LED package structure and a method for manufacturing the same, in particular, to an LED package structure for increasing heat-dissipating efficiency and a method of manufacturing the same.

2. Description of Related Art

Light-Emitting Diodes (LED) are widely used in electronic devices or on lamp illumination. Generally, the package substrate of a high power LED is applied as a ceramic substrate. Though, the technique of the manufacture of the ceramic substrate is high, the fragile characteristic and great expense restricts the LED package design. Due to the advantage of low expense of silicon wafer, the manufacturing technology has reached maturity for designing structures in the wafer, and the thermal conductivity of silicon is also close to the ceramic material, though the manufacturing cost of silicon substrate is lower than the manufacturing cost of ceramic substrate, it is possible to save costs for applying a silicon substrate without any adverse effects of the thermal conduction reduction.

As in the LED structure of the surface attaching type in prior art, the installed section of the LED chip is defined by the package base of an aperture rendering the light radiate. During the LED chip operation, some light beaming toward the base sidewall is absorbed or lost through reflecting or scattering, and there is only a small amount of light that can project out through the aperture. Thus the output efficiency is reduced for the absorption of the light causing the power loss. And the accompanying heat accumulation of the LED operation is another disadvantage against the luminous efficiency.

Referring to FIG. 1, the prior art provides an LED packaged structure including at least two substrates 10a, an insulative body 20a with a reflective groove cover the two substrates 10a, an LED 30a disposed on one of the two substrates 10a and electrically connected between two substrates 10a by two conductive wires W, and a packaged gel 40a filled into the reflective groove and cover the LED 30a. However, the insulative body 20a is formed by injection molding to cover and connect the two substrates 10a, so that the method of forming the insulative body 20a is limited in the prior art.

### SUMMARY OF THE INVENTION

In view of the aforementioned issues, the present invention provides an LED package structure and a method of manufacturing the same in order to increase heat-dissipating efficiency.

To achieve the above-mentioned objectives, the present invention provides a method of manufacturing an LED package structure for increasing heat-dissipating efficiency, including: providing a substrate element; removing one part of the substrate element in order to form at least two substrate bodies separated from each other and at least one gap between the at least two substrate bodies; forming at least one insulative layer into the at least one gap in order to connect the at least two substrate bodies with each other by the at least one insulative layer; positioning at least one light-emitting element on one of the at least two substrate bodies; electrically connecting the at least one light-emitting element between the at least two substrate bodies; and forming at least one packaged gel on the at least two substrate bodies and the at least one insulative layer in order to cover the at least one light-emitting element.

To achieve the above-mentioned objectives, the present invention provides a method of manufacturing an LED package structure for increasing heat-dissipating efficiency, including: providing a substrate element; removing one part of the substrate element in order to form at least three substrate bodies separated from each other and at least two gaps, wherein the at least three substrate bodies are divided into a middle substrate and two lateral substrates respectively disposed beside two lateral sides of the middle substrate, one of the at least two gaps is formed between the middle substrate and one of the two lateral substrate, and other one of the at least two gaps is formed between the middle substrate and other one of the two lateral substrate; respectively forming at least two insulative layers into the at least two gaps in order to connect the at least three substrate bodies with each other by the at least two insulative layers; positioning at least one light-emitting element on the middle substrate; electrically connecting the at least one light-emitting element between the two lateral substrates; and forming at least one packaged gel on the at least three substrate bodies and the at least two insulative layers in order to cover the at least one light-emitting element.

To achieve the above-mentioned objectives, the present invention provides an LED package structure for increasing heat-dissipating efficiency, including: a substrate unit, an insulative unit, a light-emitting unit and a package unit. The substrate unit has at least two substrate bodies separated from each other and at least one gap between the at least two substrate bodies. The insulative unit has at least one insulative layer formed into the at least one gap for connecting the at least two substrate bodies with each other. The light-emitting unit has at least one light-emitting element disposed on the substrate unit and electrically connected between the at least two substrate bodies. The package unit has at least one packaged gel disposed on the substrate unit and covering the at least one light-emitting element.

Therefore, the present invention can use at least one insulative layer to connect at least two substrate bodies with each other and the top surface of the insulative layer and the top surface of each substrate body are coplanar, so that many packaged gels are manufactured by the top mold with many concave spaces at the same time for respectively covering the light-emitting elements at the same time in order to achieve the objective of mass production.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a cross-sectional, schematic view of the LED package structure according to the prior art;

FIG. 2 is a flowchart of the method of manufacturing an LED package structure according to the first embodiment of the present invention;

FIGS. 2A to 2F are schematic views of the LED package structure according to the first embodiment of the present invention, at different stages of the packaging processes, respectively;

FIG. 2G is a cross-sectional, schematic view of the LED package structure according to the first embodiment of the present invention;

FIG. 3 is a cross-sectional, schematic view of the LED package structure according to the second embodiment of the present invention;

FIG. 4 is a cross-sectional, schematic view of the LED package structure according to the third embodiment of the present invention;

FIG. 5 is a flowchart of the method of manufacturing an LED package structure according to the fourth embodiment of the present invention;

FIGS. 5A to 5F are schematic views of the LED package structure according to the fourth embodiment of the present invention, at different stages of the packaging processes, respectively;

FIG. 5G is a cross-sectional, schematic view of the LED package structure according to the fourth embodiment of the present invention;

FIG. 6 is a cross-sectional, schematic view of the LED package structure according to the fifth embodiment of the present invention; and

FIG. 7 is a perspective, schematic view of the LED package structures according to the first embodiment of the present invention.

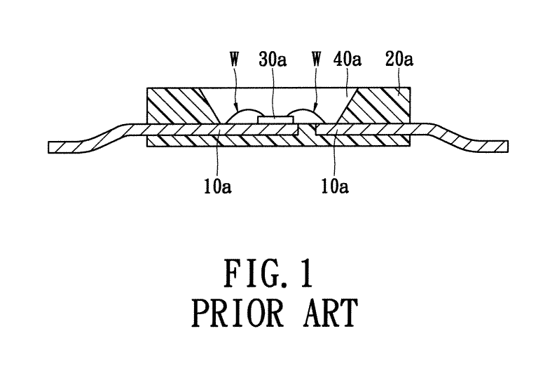

### DETAILED DESCRIPTION OF THE PREFERRED EMBODIMENTS

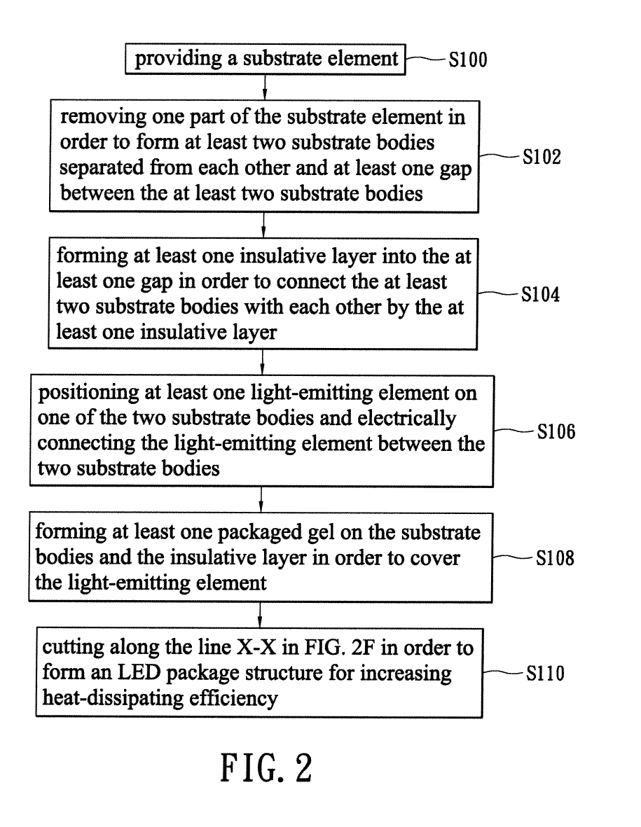

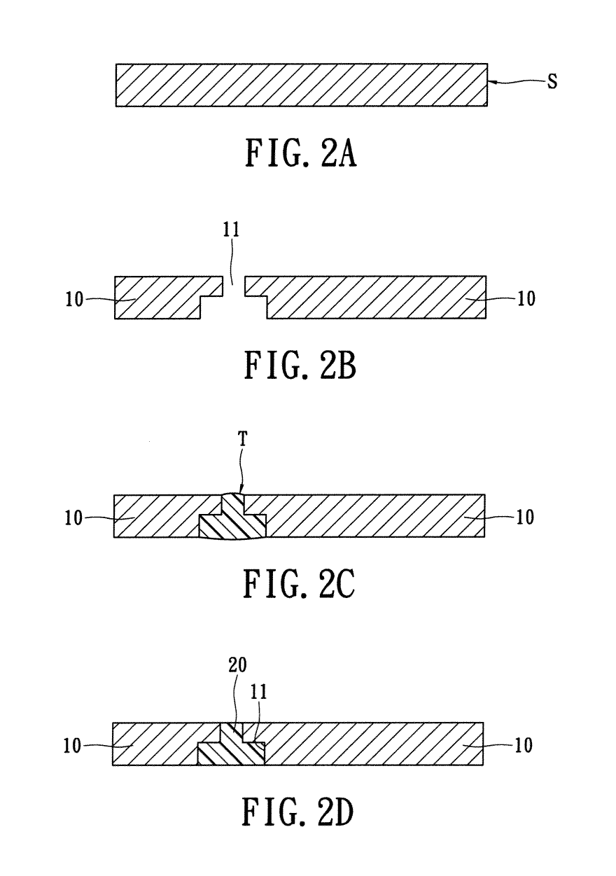

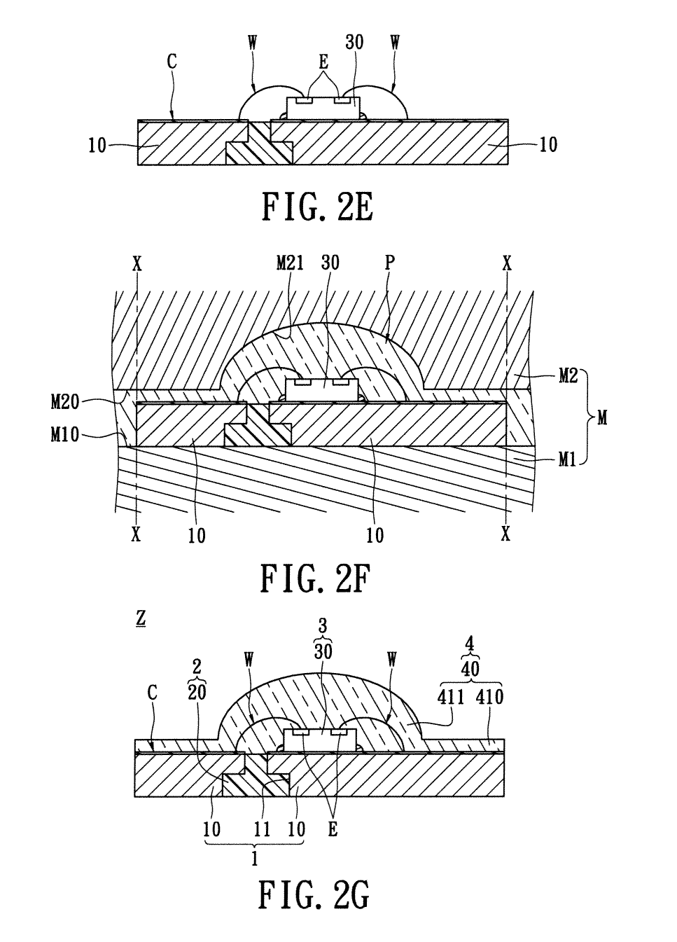

Referring to FIGS. 2 and 2A-2G, the first embodiment of the present invention provides a method of manufacturing an LED package structure for increasing heat-dissipating efficiency, including the following steps:

The step S100 is: referring to FIGS. 2 and 2A, providing a substrate element S that may be made of metal material such as copper, hence the substrate element S has electricity-conducting and heat-conducting functions.

The step S102 is: referring to FIGS. 2, 2A and 2B, removing one part of the substrate element S in order to form at least two substrate bodies 10 separated from each other and at least one gap 11 between the at least two substrate bodies 10. In addition, the two substrate bodies 10 are conductive elements. The step of removing one part of the substrate element S is finished by etching. One part of the gap 11 is formed on a bottom portion of each substrate body 10, so that the gap 11 may be a two-step opening as shown in FIG. 2B.

The step S104 is: referring to FIGS. 2, 2C and 2D, forming at least one insulative layer 20 into the at least one gap 11 in order to connect the at least two substrate bodies 10 with each other by the at least one insulative layer 10 (as shown in FIG. 2D). One part of the gap 11 is formed on the bottom portion of each substrate body 10, so that one part of the insulative layer 20 is formed on the bottom portion of each substrate body 10. Therefore, the insulative layer 20 is shown as a two-step body in FIG. 2D, so that the insulative layer 20 can strengthen the bonding force between the two substrate bodies 10. In addition, the step of forming the insulative layer 20 into the gap 11 further includes filling an insulative material T between the two substrate bodies 10 (as shown in FIG. 2C), and then removing a top portion and a bottom portion of the insulative material T in order to form the insulative layer 20 (as shown in FIG. 2D). A top surface of the insulative layer 20 and a top surface of each substrate body 10 are coplanar, and a bottom surface of the insulative layer 20 and a bottom surface of each substrate body 10 are coplanar.

The step S106 is: referring to FIGS. 2 and 2E, positioning at least one light-emitting element 30 on one of the two substrate bodies 10 and electrically connecting the light-emitting element 30 between the two substrate bodies 10. For example, the light-emitting element 30 has at least two electrodes E disposed on a top surface thereof, and the electrodes E are respectively electrically connected to two surfaces of the substrate bodies 10 by two conductive wires W. In addition, before the step of positioning the light-emitting element 30, the method of the present invention further includes forming a metal layer C on top surfaces of the substrate bodies 10. The metal layer C is helpful to the conductive wires W to attach to the surface of the substrate body 10. The metal layer C may be nickel, silver or gold etc.

The step S108 is: referring to FIGS. 2, 2F and 2G forming at least one packaged gel 40 on the substrate bodies 10 and the insulative layer 20 in order to cover the light-emitting element 30 (as shown in FIG. 2G).

For example, referring to FIG. 2F, the step of S108 includes providing a mold unit M that has a bottom mold M1 and a top mold M2 above the bottom mold M1, and the bottom mold M1 having a top plane M10 formed on a top surface thereof, and the top mold M2 having a bottom plane M20 formed on a bottom surface thereof and a concave space M21 concaved inwards from the bottom plane M20; placing the substrate bodies 10 on the top plane M10 of the bottom mold M1, and the top mold M2 being disposed above the substrate bodies 10, and the light-emitting element 30 corresponding to the concave space M21 of the top mold M2; and then filling packaged material P between the top mold M2 and the bottom mold M1 in order to form the packaged gel 40 (as shown in FIG. 2G), and the packaged gel 40 having a gel base 410 formed on the substrate bodies 10 and a gel lens 411 formed above the light-emitting element 30 and integrated with the gel base 410.

The step S110 is: referring to FIGS. 2 and 2G, cutting along the line X-X in FIG. 2F in order to form an LED package structure Z for increasing heat-dissipating efficiency.

In other words, the first embodiment of the present invention provides an LED package structure Z for increasing heat-dissipating efficiency, including: a substrate unit 1, an insulative unit 2, a light-emitting unit 3 and a package unit 4.

The substrate unit 1 has at least two substrate bodies 10 separated from each other and at least one gap 11 between the substrate bodies 10. The insulative unit 2 has at least one insulative layer 20 formed into the gap 11 for connecting the substrate bodies 10 with each other. In addition, a top surface of the insulative layer 20 and a top surface of each substrate body 10 are coplanar, and a bottom surface of the insulative layer 20 and a bottom surface of each substrate body 10 are coplanar. The light-emitting unit 3 has at least one light-emitting element 30 disposed on the substrate unit 1 and electrically connected between the substrate bodies 10. The light-emitting element 30 has at least two electrodes E disposed on a top surface thereof, and the electrodes E are respectively electrically connected to two surfaces of the substrate bodies 10 by two conductive wires W. The package unit 4 has at least one packaged gel 40 disposed on the substrate unit 1 and covering the light-emitting element 30. The packaged gel 40 has a gel base 410 formed on the substrate bodies 10 and a gel lens 411 formed above the light-emitting element 30 and integrated with the gel base 410.

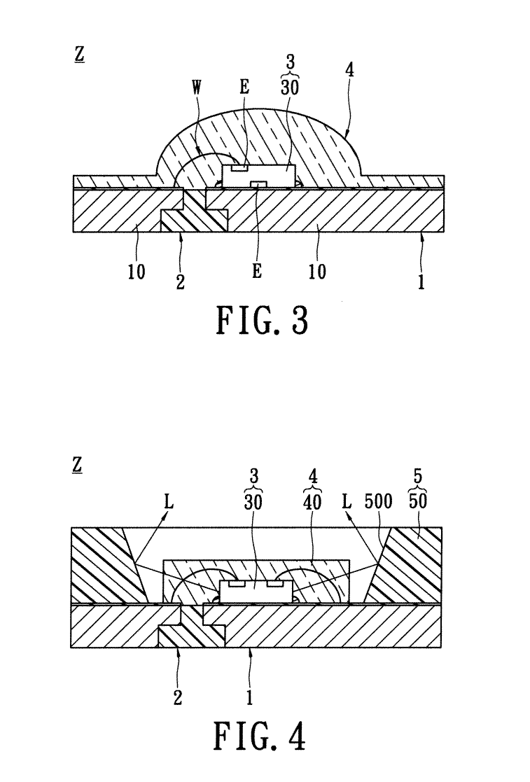

Referring to FIG. 3, the second embodiment of the present invention provides an LED package structure Z for increasing heat-dissipating efficiency, including: a substrate unit 1, an insulative unit 2, a light-emitting unit 3 and a package unit 4. The difference between the second embodiment and the first embodiment is that: the light-emitting element 30 has at least two electrodes E respectively disposed on a top surface and a bottom surface thereof, one of the electrodes E on the bottom surface of the light-emitting element 30 is directly electrically connected to one of the substrate bodies 10, and other one of the electrodes E on the top surface of the light-emitting element 30 is electrically connected to other one of the substrate bodies 10 by a conductive wire W.

Referring to FIG. 4, the third embodiment of the present invention provides an LED package structure Z for increasing heat-dissipating efficiency, including: a substrate unit 1, an insulative unit 2, a light-emitting unit 3 and a package unit 4. The difference between the third embodiment and the first embodiment is that: the third embodiment further includes a reflecting unit 5 that has at least one reflecting element 50 disposed on the substrate unit 1 and around the packaged gel 40, and the reflecting element 50 has an inclined surface 500 formed on an inner surface thereof for reflecting light beams L generated by the light-emitting element 30.

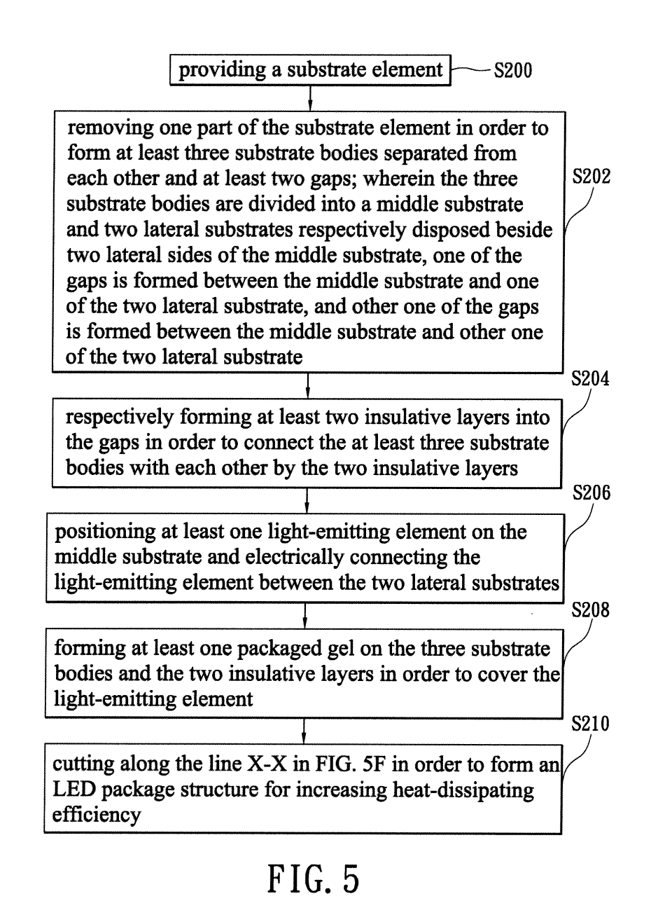

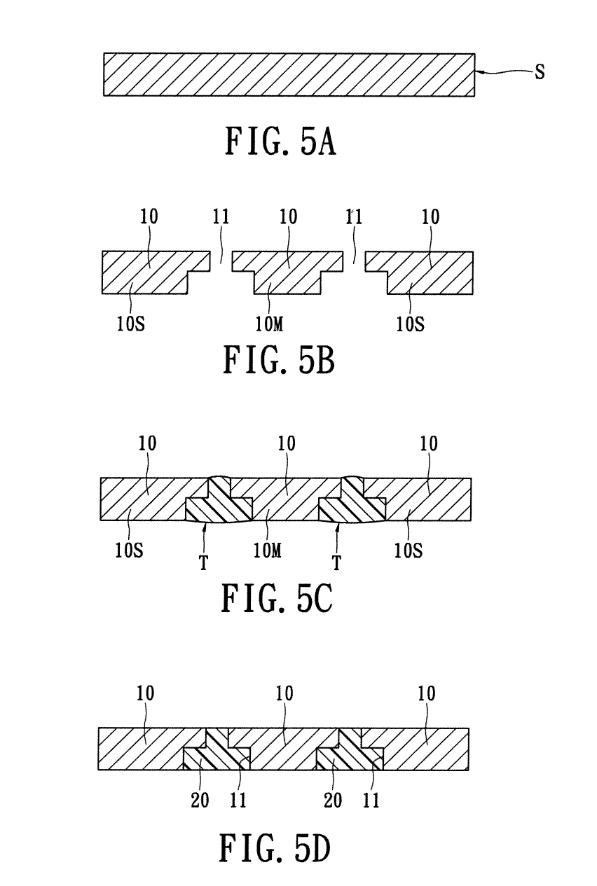

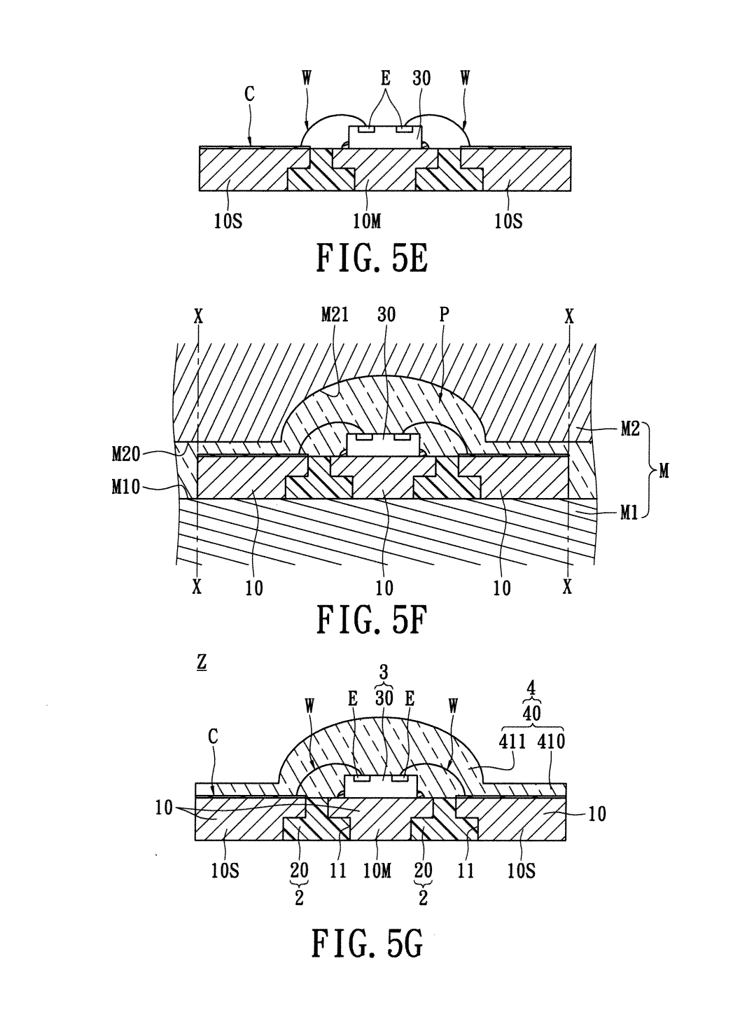

Referring to FIGS. 5 and 5A-5G, the fifth embodiment of the present invention provides a method of manufacturing an LED package structure for increasing heat-dissipating efficiency, including the following steps:

The step S200 is: referring to FIGS. 5 and 5A, providing a substrate element S that may be made of metal material such as copper, hence the substrate element S has electricity-conducting and heat-conducting functions.

The step S202 is: referring to FIGS. 5, 5A and 5B, removing one part of the substrate element S in order to form at least three substrate bodies 10 separated from each other and at least two gaps 11; wherein the three substrate bodies 10 are divided into a middle substrate 10M and two lateral substrates 10S respectively disposed beside two lateral sides of the middle substrate 10M, one of the gaps 11 is formed between the middle substrate 10M and one of the two lateral substrate 10S, and other one of the gaps 11 is formed between the middle substrate 10M and other one of the two lateral substrate 10S. In addition, the three substrate bodies 10 are conductive elements. The step of removing one part of the substrate element S is finished by etching. One part of each gap 11 is formed on a bottom portion of each substrate body 10, so that each gap 11 may be a two-step opening as shown in FIG. 5B.

The step S204 is: referring to FIGS. 5, 5C and 5D, respectively forming at least two insulative layers 20 into the gaps 11 in order to connect the at least three substrate bodies 10 with each other by the two insulative layers 20 (as shown in FIG. 5D). One part of each gap 11 is formed on the bottom portion of each substrate body 10, so that one part of each insulative layer 20 is formed on the bottom portion of each substrate body 10. Therefore, each insulative layer 20 is shown as a two-step body in FIG. 5D, so that each insulative layer 20 can strengthen the bonding force between the three substrate bodies 10. In addition, the step of respectively forming the insulative layers 20 into the gaps 11 further includes respectively filling two insulative materials T between the middle substrate 10M and one of the two lateral substrate 10S and between the middle substrate 10M and other one of the two lateral substrates 10S (as shown in FIG. 5C), and then removing a top portion and a bottom portion of each insulative material T in order to form the insulative layers 20. A top surface of each insulative layer 20 and a top surface of each substrate body 10 are coplanar, and a bottom surface of each insulative layer 20 and a bottom surface of each substrate body 10 are coplanar.

The step S206 is: referring to FIGS. 5 and 5E, positioning at least one light-emitting element 30 on the middle substrate 10M and electrically connecting the light-emitting element 30 between the two lateral substrates 10S.

For example, the light-emitting element 30 has at least two electrodes E disposed on a top surface thereof, and the electrodes E are respectively electrically connected to two surfaces of the two lateral substrates 10S by two conductive wires W. In addition, before the step of positioning the light-emitting element 30, the method of the present invention further includes respectively forming two metal layers C on two top surfaces of the two lateral substrates 10S. The metal layer C is helpful to the conductive wires W to attach to the surface of the substrate body 10. The metal layer C may be nickel, silver or gold etc.

The step S208 is: referring to FIGS. 5, 5F and 5G, forming at least one packaged gel 40 on the three substrate bodies 10 and the two insulative layers 20 in order to cover the light-emitting element 30 (as shown in FIG. 5G).

For example, referring to FIG. 5F, the step of S208 includes providing a mold unit M that has a bottom mold M1 and a top mold M2 above the bottom mold M1, and the bottom mold M1 having a top plane M10 formed on a top surface thereof, and the top mold M2 having a bottom plane M20 formed on a bottom surface thereof and a concave space M21 concaved inwards from the bottom plane M20; placing the three substrate bodies 10 on the top plane M10 of the bottom mold M1, and the top mold M2 being disposed above the three substrate bodies 10, and the light-emitting element 30 corresponding to the concave space M21 of the top mold M2; and then filling packaged material P between the top mold M2 and the bottom mold M1 in order to form the packaged gel 40 (as shown in FIG. 5G), and the packaged gel 40 having a gel base 410 formed on the three substrate bodies 10 and a gel lens 411 formed above the light-emitting element 30 and integrated with the gel base 410.

The step S210 is: referring to FIGS. 5 and 5G, cutting along the line X-X in FIG. 5F in order to form an LED package structure Z for increasing heat-dissipating efficiency.

In other words, the fourth embodiment of the present invention provides an LED package structure Z for increasing heat-dissipating efficiency, including: a substrate unit 1, an insulative unit 2, a light-emitting unit 3 and a package unit 4.

The substrate unit 1 has at least three substrate bodies 10 separated from each other and at least two gaps 11. The three substrate bodies 10 are divided into a middle substrate 10M and two lateral substrates 10S respectively disposed beside two lateral sides of the middle substrate 10M, one of the gaps 11 is formed between the middle substrate 10M and one of the two lateral substrate 10S, and other one of the gaps 11 is formed between the middle substrate 10M and other one of the two lateral substrate 10S. The insulative unit 2 has at least two insulative layers 20 filled into the gaps 11 in order to connect the at least three substrate bodies 10 with each other by the two insulative layers 20. In addition, a top surface of each insulative layer 20 and a top surface of each substrate body 10 are coplanar, and a bottom surface of each insulative layer 20 and a bottom surface of each substrate body 10 are coplanar. The light-emitting unit 3 has at least one light-emitting element 30 disposed on the middle substrate 10M and electrically connected between the two lateral substrates 10S. The package unit 4 has at least one packaged gel 40 disposed on the substrate unit 1 and covering the light-emitting element 30. The packaged gel 40 has a gel base 410 formed on the substrate bodies 10 and a gel lens 411 formed above the light-emitting element 30 and integrated with the gel base 410.

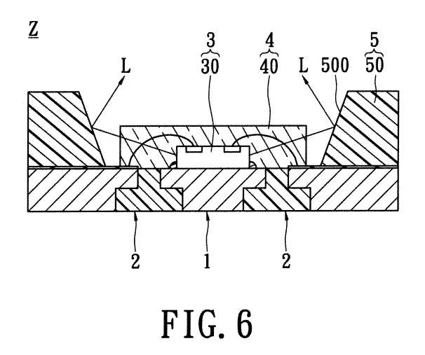

Referring to FIG. 6, the fifth embodiment of the present invention provides an LED package structure Z for increasing heat-dissipating efficiency, including: a substrate unit 1, an insulative unit 2, a light-emitting unit 3 and a package unit 4. The difference between the fifth embodiment and the fourth embodiment is that: the fifth embodiment further includes a reflecting unit 5 that has at least one reflecting element 50 disposed on the substrate unit 1 and around the packaged gel 40, and the reflecting element 50 has an inclined surface 500 formed on an inner surface thereof for reflecting light beams L generated by the light-emitting element 30.

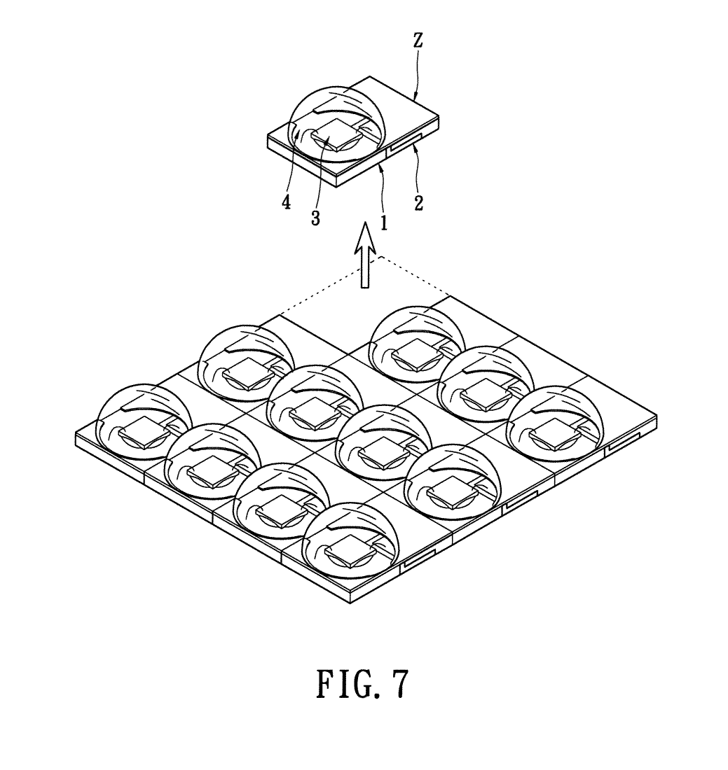

Furthermore, the present invention can manufacture many LED package structures Z at the same time. For example, referring to FIG. 7, each LED package structure Z includes a substrate unit 1, an insulative unit 2, a light-emitting unit 3 and a package unit 4. In other words, the present invention can provides a plurality of substrate elements 1 and a plurality of insulative units 2 applied to the substrate elements 1. The light-emitting unit 2 has a plurality of light-emitting elements 30 disposed on and electrically connected to the substrate unit 1, and a top mold M2 with many concave spaces M21 similar to FIG. 2F or 5F is used to form many packaged gels 40 for covering the light-emitting elements 30 in order to achieve the objective of mass production.

In conclusion, the present invention can use at least one insulative layer to connect at least two substrate bodies with each other and the top surface of the insulative layer and the top surface of each substrate body are coplanar, so that many packaged gels are manufactured by the top mold with many concave spaces at the same time for respectively covering the light-emitting elements at the same time in order to achieve the objective of mass production.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A method of manufacturing an LED package structure, comprising:
providing a substrate element;
removing one part of the substrate element in order to form at least two substrate bodies separated from each other and at least one gap between the at least two substrate bodies;
forming at least one insulative layer into the at least one gap in order to connect the at least two substrate bodies with each other by the at least one insulative layer;
positioning at least one light-emitting element on one of the at least two substrate bodies;
electrically connecting the at least one light-emitting element between the at least two substrate bodies; and
forming at least one packaged gel on the at least two substrate bodies and the at least one insulative layer in order to cover the at least one light-emitting element.

2. The method according to claim 1, wherein the step of removing one part of the substrate element is finished by etching, and one part of the at least one gap is formed on a bottom portion of each substrate body, so that one part of the at least one insulative layer is formed on the bottom portion of each substrate body.

3. The method according to claim 1, wherein the step of forming the at least one insulative layer into the at least one gap further comprises:
filling an insulative material between the at least two substrate bodies; and
removing a top portion and a bottom portion of the insulative material in order to form the at least one insulative layer, wherein a top surface of the at least one insulative layer and a top surface of each substrate body are coplanar, and a bottom surface of the at least one insulative layer and a bottom surface of each substrate body are coplanar.

4. The method according to claim 1, wherein before the step of positioning the at least one light-emitting element, the method further comprises forming a metal layer on top surfaces of the at least two substrate bodies.

5. The method according to claim 1, wherein the at least one light-emitting element has at least two electrodes disposed on a top surface thereof, and the at least two electrodes are respectively electrically connected to two surfaces of the at least two substrate bodies by two conductive wires.

6. The method according to claim 1, wherein the at least one light-emitting element has at least two electrodes respectively disposed on a top surface and a bottom surface thereof, one of the at least one electrodes on the bottom surface of the at least one light-emitting element is directly electrically connected to one of the at least two substrate bodies, and other one of the at least one electrodes on the top surface of the at least one light-emitting element is electrically connected to other one of the at least two substrate bodies by a conductive wire.

7. The method according to claim 1, wherein the step of forming the at least one packaged gel further comprises:
providing a mold unit that has a bottom old and a top mold above the bottom mold, wherein the bottom mold has a top plane formed on a top surface thereof, and the top mold has a bottom plane formed on a bottom surface thereof and a concave space concaved inwards from the bottom plane;
placing the at least two substrate bodies on the top plane of the bottom mold, wherein the top mold is disposed above the at least two substrate bodies, and the at least one light-emitting element corresponds to the concave space of the top mold; and
filling packaged material between the top mold and the bottom mold in order to form the at least one packaged gel, wherein the at least one packaged gel has a gel base formed on the at least two substrate bodies and a gel lens formed above the at least one light-emitting element and integrated with the gel base.

8. A method of manufacturing an LED package structure, comprising:
providing a substrate element;
removing one part of the substrate element in order to form at least three substrate bodies separated from each other and at least two gaps, wherein the at least three substrate bodies are divided into a middle substrate and two lateral substrates respectively disposed beside two lateral sides of the middle substrate, one of the at least two gaps is formed between the middle substrate and one of the two lateral substrate, and other one of the at least two gaps is formed between the middle substrate and other one of the two lateral substrate;
respectively forming at least two insulative layers into the at least two gaps in order to connect the at least three substrate bodies with each other by the at least two insulative layers;
positioning at least one light-emitting element on the middle substrate;
electrically connecting the at least one light-emitting element between the two lateral substrates; and
forming at least one packaged gel on the at least three substrate bodies and the at least two insulative layers in order to cover the at least one light-emitting element.

9. The method according to claim 8, wherein the step of removing one part of the substrate element is finished by etching, and one part of each gap is formed on a bottom portion of the substrate element, so that one part of each insulative layer is formed on the bottom portion of the substrate element.

10. The method according to claim 8, wherein the step of respectively forming the at least two insulative layers into the at least two gaps further comprises:
respectively filling two insulative materials between the middle substrate and one of the two lateral substrate and between the middle substrate and other one of the two lateral substrates; and
removing a top portion and a bottom portion of each insulative material in order to form the at least two insulative layers, wherein a top surface of each insulative layer and a top surface of each substrate body are coplanar, and a bottom surface of each insulative layer and a bottom surface of each substrate body are coplanar.

11. The method according to claim 8, wherein before the step of positioning the at least one light-emitting element, the method further comprises respectively forming two metal layers on two top surfaces of the two lateral substrates.

12. The method according to claim 8, wherein the at least one light-emitting element has at least two electrodes disposed on a top surface thereof, and the at least two electrodes are respectively electrically connected to two surfaces of the two lateral substrates by two conductive wires.

13. The method according to claim 8, wherein the step of forming the at least one packaged gel further comprises:
providing a mold unit that has a bottom mold and a top mold above the bottom mold, wherein the bottom mold has a top plane formed on a top surface thereof, and the top mold has a bottom plane formed on a bottom surface thereof and a concave space concaved inwards from the bottom plane;
placing the at least three substrate bodies on the top plane of the bottom mold, wherein the top mold is disposed above the at least three substrate bodies, and the at least one light-emitting element corresponds to the concave space of the top mold; and
filling packaged material between the top mold and the bottom mold in order to form the at least one packaged gel, wherein the at least one packaged gel has a gel base formed on the at least three substrate bodies and a gel lens formed above the at least one light-emitting element and integrated with the gel base.

14. An LED package structure, comprising:
a substrate unit having at least two substrate bodies separated from each other and at least one gap between the at least two substrate bodies;
an insulative unit having at least one insulative layer formed into the at least one gap for connecting the at least two substrate bodies with each other;
a light-emitting unit having at least one light-emitting element disposed on the substrate unit and electrically connected between the at least two substrate bodies; and
a package unit having at least one packaged gel disposed on the substrate unit and covering the at least one light-emitting element.

15. The LED package structure according to claim 14, wherein the at least two substrate bodies are conductive substances, and each substrate body has a metal layer formed on a top surface thereof.

16. The LED package structure according to claim 14, further comprising:
a reflecting unit that has at least one reflecting element disposed on the substrate unit and around the at least one packaged gel, and the at least one reflecting element has an inclined surface formed on an inner surface thereof for reflecting light beams generated by the at least one light-emitting element.

17. The LED package structure according to claim 14, wherein the at least one packaged gel has a gel base formed on the at least two substrate bodies and a gel lens formed above the at least one light-emitting element and integrated with the gel base.

18. The LED package structure according to claim 14, wherein one part of the at least one gap is formed on a bottom portion of each substrate body, so that one part of the at least one insulative layer is formed on the bottom portion of each substrate body.
